(19) United States
(12) Patent Application Publication
(10) Pub. No.: US 2009/0166185 A1
(43) Pub. Date: Jul. 2, 2009

(54) ION ASSISTED DEPOSITION METHOD FOR FORMING MULTILAYER FILM

(75) Inventor: SHIH-CHE CHIEN, Tu-Cheng (TW)

Correspondence Address: PCE INDUSTRY, INC.;ATT. Steven Reiss, 458 E. LAMBERT ROAD, FULLERTON, CA, 92835, US

(73) Assignee: HON HAI PRECISION INDUSTRY CO., LTD., Tu-Cheng (TW)

(21) Appl. No.: 12/189,097

(22) Filed: Aug. 8, 2008

(30) Foreign Application Priority Data
Dec. 27, 2007 (CN) 200710203468.0

(51) Int. Cl. C23C 14/34

(52) U.S. Cl. 204/192.11

(57) ABSTRACT

An ion assisted deposition (IAD) method for forming a film on a substrate is disclosed. The film includes a number of layers. The substrate is bombarded by an ion source with a low ion energy at a initial period of forming each of the layers and a high ion energy during a majority period of forming each of the layers after the respective initial period.

### BACKGROUND

1. Field of the Invention

The present invention relates to deposition methods of films and, particularly, to an ion assisted deposition (IAD) method for forming a multilayer film.

2. Description of the Related Art

Films are coated on plastics, e.g., acrylics, to provide optical properties such as antireflection or high reflection, thereby forming various optical elements such as lenses. Deposition of films on plastics is a challenging job due to the differences between thermal expansion coefficients of plastics and film materials. The films coated on the plastic may suffer from poor adhesion and are less stable due to induced thermal stress, resulting cracks occurring thereof, especially for which are coated on lenses having a great curvature radius. In order to improve adhesion of the films, an ion assisted deposition (IAD) method has been proposed. Ions are used in the IAD method for providing energy to condense the atoms and molecules of the films during deposition. However, these ions also increase the internal stress between the plastics and the films, and layers of the films.

Therefore, it is desirable to provide an ion assisted deposition method for forming a multilayer film, which can overcome the above-mentioned problem.

### SUMMARY

In an exemplary embodiment, an ion assisted deposition (IAD) method for forming a film on a substrate is disclosed. The film includes a number of layers. The substrate is bombarded by an ion source with a low ion energy at a initial period of forming each of the layers and a high ion energy during a majority period of forming each of the layers after the respective initial period.

### BRIEF DESCRIPTION OF THE DRAWINGS

FIG. 1 is a flowchart of an ion assisted deposition (IAD) method, according to an exemplary embodiment.

FIG. 2 is a schematic view of equipment for performing the IAD method of FIG. 1.

FIG. 3 is a graph showing how ion energy changes in the exemplary embodiment.

FIG. 4 is a graph showing how gas flux changes in the exemplary embodiment.

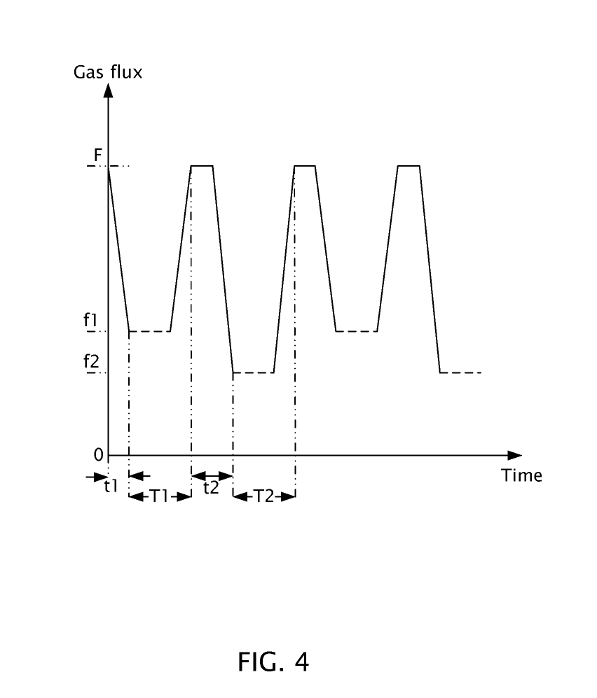

### DETAILED DESCRIPTION

Embodiments of the present ion assisted deposition (IAD) method will now be described in detail with reference to the drawings.

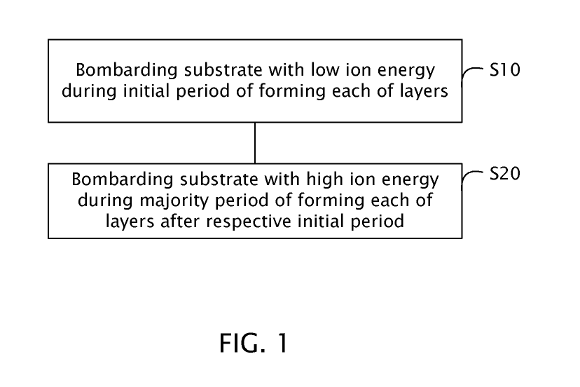

Referring to FIG. 1, an IAD method for forming a film on a substrate, according to an exemplary embodiment, is disclosed. The film includes a number of layers. The IAD method includes the following steps S10˜S20.

Step S10: bombarding the substrate using an ion source with a low ion energy at an initial period of forming each of the layers using deposition method.

Step S20: bombarding the substrate with a high ion energy during a majority period of forming each the layers after the respective initial period.

The IAD method may combine ion bombardment with simultaneous sputtering deposition or physical vapor deposition techniques. The substrate may be a plastic or glass lens, or other optical elements. The film may be an antireflection film or a high reflection film.

A detailed example of the IAD method is given below. This example combines ion bombardment with a common physical evaporation technique: vacuum evaporation to form a 4-layer: TiO₂—SiO₂—TiO₂—SiO₂ antireflection film on a plastic, e.g., polymethyl methacrylate, lens.

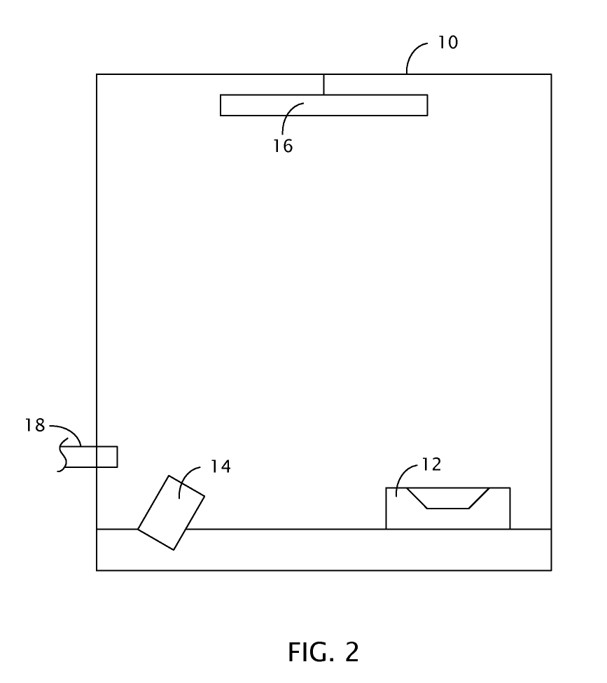

Referring to FIG. 2, a chamber 10, an evaporator 12 and an ion source 14 are provided. The chamber 10 is configured for providing desired conditions, e.g., desired pressure and temperature, for the deposition of the film. The evaporator 12 is sealed in the chamber 10 and is configured for evaporating Ti or Si. The ion source 14 is sealed in the chamber 10 and is configured for bombarding the lens 16 during the deposition. Also, a gas inlet 18 is provided and configured to introduce a reactive gas, e.g., oxygen into the chamber 10. The reactive gas reacts with Ti and Si and thereby forms gaseous film materials: TiO₂ and SiO₂, and is ionized by the ion source to form oxygenic ions. Then, the chamber 10 is evacuated to a desired pressure about 1.33×10⁻⁴ Pa and heated to a desired temperature about 50˜90° C.

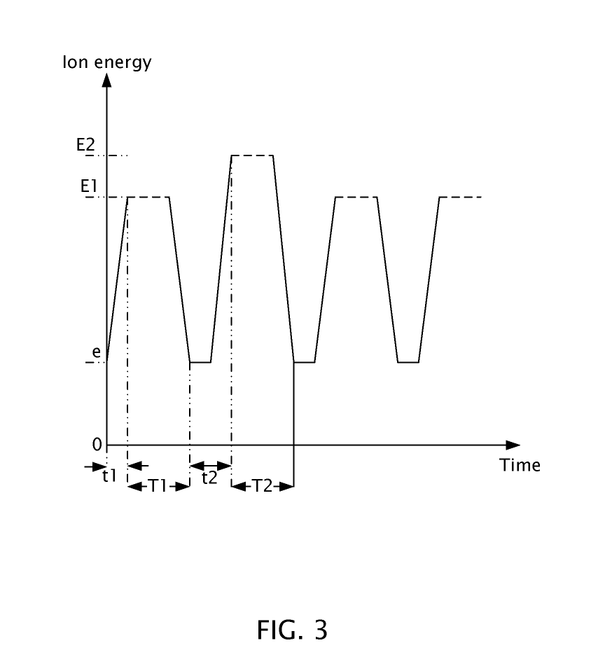

Referring to FIG. 3, given the desired deposition conditions, the film material TiO₂ is coated to the lens 16. At a first initial period ‘t1’ of the coating of TiO₂, the ion source 16 bombards the lens 16 with low energy ‘e’. Next, during a first majority period ‘T1’ of the deposition of the film material TiO₂, the ion source bombards the lens 16 with first high energy ‘E1’. Where, t1 is about 5˜60 seconds and T1 is about 300˜900 seconds depending on the thickness of the layer, e is about 20˜40 watts and E1 is about 40˜2000 watts. Also shown in FIG. 2, at a second initial period ‘t2’ of the deposition of SiO₂, the ion source bombards the lens 16 with low energy e. Next, during a second time ‘T2’ of the deposition of the SiO₂, the ion source 16 bombards the substrate with second high energy ‘E2’. Where, t2 is about 5˜60 seconds and T2 is about 300˜900 seconds depending on the thickness of the layer, E1 is about 40˜2000 watts.

Also referring to FIG. 3, the flux of reactive gas can be accordingly controlled to improve the optical properties and mechanical properties of the film. As shown in FIG. 3, during the first initial period t1 of the deposition of TiO₂, the gas flux is controlled at a high value ‘F’. During the first majority period T1 of the deposition of TiO₂, the gas flux is controlled at a first low value f1. Where F is about 15˜60 sccm, and f1 is about 15˜60 sccm. Also shown in FIG. 3, during the second initial period t2 of the deposition of SiO₂, the gas flux is controlled at the high value ‘F’. During the second majority period T2 of the deposition of TiO₂, the gas flux is controlled at a second low level f2, where f2 is about 0.1˜15 sccm.

It should be understood that all parameters are exemplarily given for the better understanding of the IAD method and should not be limited to the described example. All these parameters should be set depending on film materials and/or requirements of optical properties and performances of the film.

It will be understood that the above particular embodiments and methods are shown and described by way of illustration only. The principles and the features of the present invention may be employed in various and numerous embodiment thereof without departing from the scope of the invention as claimed. The above-described embodiments illustrate the scope of the invention but do not restrict the scope of the invention.

What is claimed is:

1. An ion assisted deposition method for forming a film on a substrate, the film including a plurality of layers, comprising:
bombarding the substrate using an ion source with a low ion energy during an initial period of forming each of the layers using a deposition method; and
bombarding the substrate using the ion source with a high ion energy during a majority period of forming each of the layers after the respective initial period.

2. The ion assisted deposition method as claimed in claim 1, wherein the deposition method is selected from the group consisting of sputtering deposition and physical evaporation deposition.

3. The ion assisted deposition method as claimed in claim 1, wherein the film is selected from the group consisting of an antireflection film and a high reflection film.

4. The ion assisted deposition method as claimed in claim 1, wherein the substrate is lens.

5. The ion assisted deposition method as claimed in claim 1, wherein the deposition method is vacuum evaporation method, the substrate being a plastic lens, the film being an antireflection film including a plurality of layers of TiO₂ and SiO₂ stacked alternately one on another.

6. The ion assisted deposition method as claimed in claim 5, further comprising:
providing a chamber with an evaporator, an ion source and a gas inlet, the evaporator being sealed in the chamber and configured for evaporating Ti and Si, the ion source being sealed in the chamber and configured for bombarding the lens during forming the film, the gas inlet being configured to introduce a reactive gas, the reactive gas being configured for reacting with Ti and Si and thereby forming gaseous film materials TiO₂ and SiO₂, and being ionized into ions.

7. The ion assisted deposition method as claimed in claim 6, further comprising:
evacuating the chamber to about 1.33×10⁻⁴ Pa; and
heating the chamber to about 50˜90° C.

8. The ion assisted deposition method as claimed in claim 5, wherein the low ion energy is about 20˜40 watts.

9. The ion assisted deposition method as claimed in claim 5, wherein the high ion energy ranges from 40˜2000 watts.

10. The ion assisted deposition method as claimed in claim 5, wherein the initial period is about 5˜60 seconds.

11. The ion assisted deposition method as claimed in claim 5, wherein the majority period is about 300˜900 seconds.

12. The ion assisted deposition method as claimed in claim 5, wherein the initial period is about 5˜60 seconds.

13. The ion assisted deposition method as claimed in claim 5, wherein the majority period is about 300˜900 seconds.

14. The ion assisted deposition method as claimed in claim 5, further comprising:
introducing a reactive gas with a high flux during the initial period; and
introducing the reactive gas with a low flux during the majority period.

15. The ion assisted deposition method as claimed in claim 14, wherein the high flux is in the range from 15 sccm to 60 sccm.

16. The ion assisted deposition method as claimed in claim 14, wherein the low flux ranges from 0.1 sccm to 15 sccm.
